(19) United States
(12) Patent Application Publication
(10) Pub. No.: US 2026/0018467 A1
(43) Pub. Date: Jan. 15, 2026

(54) SYSTEMS AND METHODS FOR ANALYZING NANOTOPOGRAPHY OF FRONT-END PROCESSED SEMICONDUCTOR WAFERS

(71) Applicant: GlobalWafers Co., Ltd., Hsinchu (TW)

(72) Inventors: Yung Hsing Chu, Zhubei (TW); Yau-Ching Yang, Zhubei (TW); Yen-Chun Chou, Taoyuan City (TW); Shan-Hui Lin, Hsinchu City (TW)

(21) Appl. No.: 19/263,783

(22) Filed: Jul. 9, 2025

Related U.S. Application Data
(60) Provisional application No. 63/669,512, filed on Jul. 10, 2024.

(51) Int. Cl. H01L 21/66; G01B 11/30

(52) U.S. Cl. CPC H01L 22/12; G01B 11/30

(57) ABSTRACT

Systems and methods of processing semiconductor wafers using nanotopography analysis of a front-end processed (e.g., ground) wafer surface. The systems and methods execute a wafer analysis model that filters out roughness defects from the front-end processed wafer surface to enable the nanotopography analysis. In one example, a method of processing semiconductor wafers includes obtaining image data of a surface of a pre-polished wafer; processing the image data by: generating linear profiles of the surface, applying a regression analysis to smooth each linear profile, and recombining the smoothed linear profiles to obtain processed image data; determining a nanotopography of the surface of the pre-polished wafer from the processed image data; and based on the determined nanotopography of the surface, either sorting the pre-polished wafer for polishing or adjusting a front end process performed on the pre-polished wafer.

### CROSS-REFERENCE TO RELATED APPLICATIONS

This application claims the benefit of priority to U.S. Provisional Patent Application No. 63/669,512, filed Jul. 10, 2024, the disclosure of which is incorporated herein by reference in its entirety.

### FIELD

This disclosure relates generally to processing of semiconductor wafers and, more particularly, to systems and methods for analyzing nanotopography of front-end processed semiconductor wafers and using the analyzed nanotopography for additional processing.

### BACKGROUND

Semiconductor wafers are commonly used in the production of integrated circuit (IC) chips on which circuitry are printed. The circuitry is printed as identical integrated circuits (“die”) in miniaturized form onto surfaces of the wafers in a multi-stage fabrication process. Specifically, the process includes various stages of electron beam-lithographic or photolithographic processing steps (“lithography”) and chemical or physical processing steps (e.g., chemical mechanical polishing, etching, and passivation). At each stage, a new pattern layer is added to the surface of the wafer, or an existing layer is modified. Precise alignment of the layers (“overlay”) is critical for end performance of the chips.

Chip manufacturers require wafers that have extremely flat and parallel surfaces to mitigate or eliminate overlay error and ensure that a maximum number of chips can be fabricated from each wafer. Wafers are initially obtained from a single crystal ingot of suitable material (e.g., silicon). Wafers may be sliced from the ingot using, for example, a wire saw. The surfaces of the raw wafers are then subject to preliminary flattening and etching using additional front-end process tools, such as a grinding, lapping, or etching tool. The edges may also be ground and/or rounded using a beveling tool. The surfaces are then polished to produce a smooth, highly reflective, mirrored wafer surface.

Acceptable wafer geometry specifications can be defined by the shape and flatness of the wafer before lithography. Shape is the long wavelength component of the wafer geometry in an unchucked state, defined as the deviation of median surface of the wafer relative to a best-fit median surface reference plane. Shape can be characterized by global parameters such as warp, the sum of the maximum positive and negative deviations from the best-fit plane, and bow, the distance between the surface and the best-fit plane at a center of the wafer. Flatness is the variation of wafer thickness relative to the reference plane. Flatness can be characterized by global parameters, such as the maximum variation of wafer thickness from an ideal flat back surface (GBIR), or local parameters, such as site flatness, front reference surface, least squares reference plane, range (SFQR).

Another consideration is the topology of the wafer surface. Poor topology can lead to non-uniform oxide layer removal in a later polishing (CMP) process. This can lead to substantial yield losses for the wafer users such as chip manufacturers. As the IC manufacturers move towards smaller process technology, the tolerances for topology are projected to become tighter.

In order to identify and address topology degradation concerns, device and semiconductor material manufacturers consider the nanotopography of the wafer surfaces. For example, Semiconductor Equipment and Materials International (SEMI), a global trade association for the semiconductor industry (SEMI document 3089), defines nanotopography as the deviation of a wafer surface within a spatial wavelength of about 0.2 mm to about 20 mm. This spatial wavelength corresponds very closely to surface features on the nanometer scale for processed semiconductor wafers. Nanotopography measures elevational deviation of one surface of the wafer and does not consider thickness variations of the wafer, as with traditional flatness measurements. The nanotopography of the wafer surface can be generated using a high accuracy, optical inspection tool (e.g., a WaferSight™ 2 or 2+ bare wafer geometry metrology system manufactured by KLA-Tencor Corporation). These optical inspection tools use light reflected from a surface of the wafer to detect very small surface variations.

In the semiconductor industry, companies are competing to produce high quality silicon wafers with lower costs. Thus, having a highly efficient production process with minimum losses provides a competitive advantage. Front-end production processes like wire saw slicing and grinding result in topography features on the wafer which can lead to topography degradation. However, the typical tools available for nanotopography measurement tend to have lot of noise when measuring relatively rough surfaces of the wafer after front-end processing (e.g., wire saw slicing and grinding). After wire saw slicing, the surface roughness of the wafer is too high to use the optical inspection tool for nanotopography measurement. Grinding alleviates some of the surface roughness issues, but the ground wafer can still have surface defects (e.g., grinding and wheel spark out marks) that distort the nanotopography measuring of the optical inspection tool. The nanotopography measurement is conventionally taken using the optical inspection tool after the wafer is polished and the surface roughness defects resulting from the front-end processing have been removed.

Many wafers may be processed (e.g., polished) after wire saw slicing and grinding but before problems are detected in the front-end processes. At this stage, additional manufacturing time and costs have been invested and the polished wafer with poor nanotopography may not be salvageable. Each individual production line and front end process tools (e.g., wire saw and grinder) may have particular characteristics, which may vary from device to device, making the necessary tuning to address nanotopography issues difficult to discern and remediate. Accordingly, there is a need for a system for analyzing wafers to quickly and efficiently detect potential issues and reduce material losses while increasing efficiency.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect is a method of processing semiconductor wafers, the method comprising: obtaining image data of a surface of a pre-polished wafer; processing the image data by: generating linear profiles of the surface, applying a regression analysis to smooth each linear profile, and recombining the smoothed linear profiles to obtain processed image data; determining a nanotopography of the surface of the pre-polished wafer from the processed image data; and based on the determined nanotopography of the surface, either: sorting the pre-polished wafer for polishing; or adjusting a front end process performed on the pre-polished wafer.

Another aspect is a system for processing semiconductor wafers, the system comprising: one or more front end process devices; an inspection tool configured to obtain image data of a surface of a pre-polished wafer; and a computer device in communication with the one or more front end process devices and the inspection tool, the computer device comprising at least one processor in communication with at least one memory device, wherein the at least one processor is programmed to: generate linear profiles of the surface; apply a regression analysis to smooth each linear profile; recombine the smoothed linear profiles to obtain processed image data; determine a nanotopography of the surface of the pre-polished wafer from the processed image data; and based on the determined nanotopography of the surface, adjust a front end process performed by the one or more front end process devices on the pre-polished wafer.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is an example semiconductor wafer.

FIG. 2 is a block diagram of a system for processing semiconductor wafers.

FIG. 3 is a simplified block diagram of an example system for evaluating a wafer.

FIG. 4 is an example configuration of a client system.

FIG. 5 is an example configuration of a server system.

FIG. 6 is an example process flow for wafer analysis.

FIG. 7 is an example process flow implemented in the FIG. 6 process for filtering out surface roughness defect in a wafer surface.

FIGS. 8-12 are grayscale images of a wafer in accordance with the processes of FIGS. 6 and 7.

FIGS. 13A-13E depict a first example of filtering out surface roughness defects from a wafer surface for nanotopography analysis.

FIGS. 14A-14E depict a second example of filtering out surface roughness defects from a wafer surface for nanotopography analysis.

FIG. 15 shows a correlation between the use of the methods described herein to filter out surface roughness defects for nanotopography and post-polishing analysis.

### DETAILED DESCRIPTION

The implementations described relate to systems and methods for analyzing wafer data and, more specifically, to analyzing surfaces of front-end processed (e.g., post grinding or ground) wafers to generate a nanotopography of the wafer that can be used to determine whether the wafer is suitable for additional processing (e.g., polishing and lithography). In the embodiments described, a wafer surface analysis model is executed by a computing device to leverage the nanotopography measurement capabilities of optical inspection tools (e.g., a WaferSight™ 2 or 2+ bare wafer geometry metrology system manufactured by KLA-Tencor Corporation) while eliminating any noise in the measurement resulting from roughness defects (e.g., grinding and wheel spark out marks) on the surface of the front-end processed wafer. The generated nanotopography can be used to determine if adjustments need to be made to the front-end process tool (e.g., grinder) based on the state of the front-end processed wafer surface and one or more predetermined thresholds. The systems and methods permit nanotopography feedback in less time and with higher accuracy compared to prior processes, allowing adjustments that can be made to improve nanotopography to be recognized and implemented with less lag time for improved quality control and/or wafer yield.

Computer systems such as the wafer surface analysis computer devices and related computer systems include a processor and a memory. However, any processor in a computer device referred to herein may also refer to one or more processors wherein the processor may be in one computing device or a plurality of computing devices acting in parallel. Additionally, any memory in a computer device referred to herein may also refer to one or more memories wherein the memories may be in one computing device or a plurality of computing devices acting in parallel.

A processor may include any programmable system including systems using micro-controllers, reduced instruction set circuits (RISC), application-specific integrated circuits (ASICs), logic circuits, and any other circuit or processor capable of executing the functions described herein. The above examples are example only, and are thus not intended to limit in any way the definition and/or meaning of the term “processor.”

The term “database” may refer to either a body of data, a relational database management system (RDBMS), or to both. As used herein, a database may include any collection of data including hierarchical databases, relational databases, flat file databases, object-relational databases, object oriented databases, and any other structured collection of records or data that is stored in a computer system. The above examples are example only, and thus are not intended to limit in any way the definition and/or meaning of the term database. Examples of RDBMS' include, but are not limited to including, Oracle® Database, MySQL, IBM® DB2, Microsoft® SQL Server, Sybase®, and PostgreSQL. However, any database may be used that enables the systems and methods described herein. (Oracle is a registered trademark of Oracle Corporation, Redwood Shores, California; IBM is a registered trademark of International Business Machines Corporation, Armonk, New York; Microsoft is a registered trademark of Microsoft Corporation, Redmond, Washington; and Sybase is a registered trademark of Sybase, Dublin, California.)

A computer program of one embodiment is embodied on a computer-readable medium. In an example, the system is executed on a single computer system, without requiring a connection to a server computer. In a further example embodiment, the system is being run in a Windows® environment (Windows is a registered trademark of Microsoft Corporation, Redmond, Washington). In yet another embodiment, the system is run on a mainframe environment and a UNIX® server environment (UNIX is a registered trademark of X/Open Company Limited located in Reading, Berkshire, United Kingdom). In a further embodiment, the system is run on an iOS® environment (iOS is a registered trademark of Cisco Systems, Inc. located in San Jose, CA). In yet a further embodiment, the system is run on a Mac OS® environment (Mac OS is a registered trademark of Apple Inc. located in Cupertino, CA). In still yet a further embodiment, the system is run on Android® OS (Android is a registered trademark of Google, Inc. of Mountain View, CA). In another embodiment, the system is run on Linux® OS (Linux is a registered trademark of Linus Torvalds of Boston, MA). The application is flexible and designed to run in various different environments without compromising any major functionality. In some embodiments, the system includes multiple components distributed among a plurality of computing devices. One or more components are in the form of computer-executable instructions embodied in a computer-readable medium. The systems and processes are not limited to the specific embodiments described herein. In addition, components of each system and each process can be practiced independently and separately from other components and processes described herein. Each component and process can also be used in combination with other assembly packages and processes.

An element or step recited in the singular and proceeded with the word “a” or “an” should be understood as not excluding plural elements or steps, unless such exclusion is explicitly recited. Furthermore, references to “example embodiment” or “one embodiment” of the present disclosure are not intended to be interpreted as excluding the existence of additional embodiments that also incorporate the recited features.

The terms “software” and “firmware” are interchangeable, and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

The term “real-time” refers to at least one of the time of occurrence of the associated events, the time of measurement and collection of predetermined data, the time to process the data, and the time of a system response to the events and the environment. These activities and events occur substantially instantaneously.

The systems and processes are not limited to the specific embodiments described herein. In addition, components of each system and each process can be practiced independent and separate from other components and processes described herein. Each component and process also can be used in combination with other assembly packages and processes.

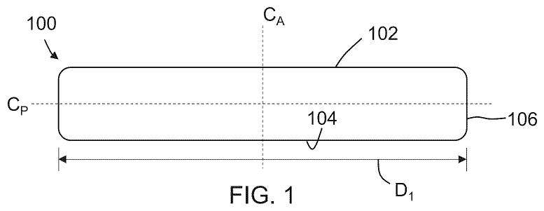

FIG. 1 depicts an example of a semiconductor (e.g., silicon) substrate 100 that is analyzed for nanotopography and processed using the generated nanotopography in accordance with systems and methods of the present disclosure. The substrate 100 is also referred to interchangeable as a “wafer”. The semiconductor material of the substrate 100 can include a single crystal semiconductor material. For example, the substrate 100 includes a single crystal semiconductor material selected from the group consisting of silicon, germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof. Single crystal semiconductor wafers (e.g., single crystal silicon wafers) can be sliced using a wire saw from a single crystal ingot grown in accordance with Czochralski crystal growing methods or float zone growing methods.

The substrate 100 includes two major, generally parallel surfaces 102, 104. One of the surfaces is a front surface 102 of the substrate 100, and the other surface is a back surface 104 of the substrate 100. The substrate 100 also includes a circumferential edge 106 joining the front surface 102 and the back surface 104. A central plane C_{P} is defined between the front surface 102 and the back surface 104 and a central axis C_{A} substantially perpendicular to the central plane C_{P}. A radial length of the substrate 100 is measured as the distance between the central axis C_{A} and the circumferential edge 106. A diameter, D₁, of the substrate 100 is measured across the circumferential edge 106. The diameter D₁ varies depending on the intended application of the substrate 100. For example, the diameter D₁ can be between 150 millimeters (mm) to 450 mm, at least 150 mm, at least 200 mm, at least 300 mm, or at least 450 mm, about 150 mm, about 200 mm, about 300 mm, or about 450 mm. A thickness of the substrate 100, measured between the front and back surfaces 102, 104, varies depending on the intended application of the substrate 100. For example, the thickness of the substrate 100 is between 250 micrometers (μm) to 1500 μm, such as between 300 μm to 1000 μm, or between 500 μm to 1000 μm, such as about 775 μm.

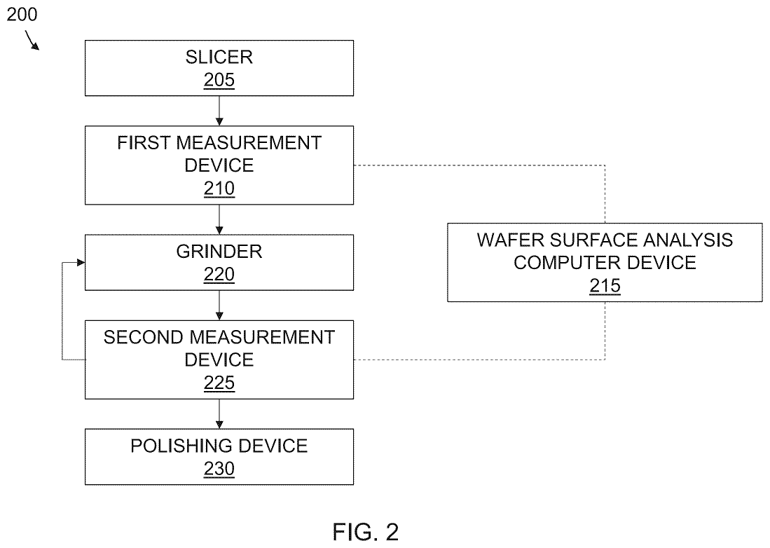

FIG. 2 is a block diagram of a system 200 for processing semiconductor wafers, such as the substrate 100. System 200 starts with a slicer 205 in the process of semiconductor wafer manufacture. The slicer 205 is a wire saw that cuts disks of semiconductor material from a single crystal ingot. Alternatively, the slicer 205 can be any suitable slicing tool for producing semiconductor wafers.

After the slicer 205 slices the wafer, the wafer is analyzed by a first measurement device 210 that measures data to generate a profile for the wafer. At this point, the wafer is unground, unetched, and unpolished. The first measurement device 210 provides the measurement data from the ground wafer to a wafer surface analysis (WSA) computer device 215. Examples of suitable geometry measurement tools used as the first measurement device 210 include Kobelco SBW series tools, Kobelco LGW series tools, and Kobelco LSW series tools. The first measurement device 210 suitably obtains measurement data of one or both surfaces that includes the surface height and the thickness of points along one or both surfaces of the wafer using a capacitance probe or laser-based distance sensor. In one example, the first measurement device 210 is a Kobelco SBW-330 tool. The WAS computer device 215 can use the measurement data from the first measurement device 210 to generate In-plane distortion (IPD) and shape distribution maps for the wafer. The IPD and shape distribution maps can be generated using Shape and GAPI RMS calculations from the measurement data. As used herein, GAPI RMS refers to a shape-based matrix that is an index for representing of the smoothness of a wafer substrate. Examples for determining the GAPI RMS metric are described in U.S. Publication No. 2023/0050442, published Feb. 16, 2023, the disclosure of which is incorporated by reference in its entirety.

The GAPI RMS can be calculated by the WSA computer device 215. First, the WSA computer device 215 loads the raw measurement data, such as from the first measurement device 210. The raw measurement data includes thickness and lower (or front) profile. The WSA computer device 215 converts the raw data to several diameter line scan profiles. The number of diameter scan profiles could be 2, 4, 8, or more. The WSA computer device 215 calculates the least squares best fitting to the thickness plane. The WSA computer device 215 calculates the raw shape diameter scan profiles by low profile plus half of the thickness-best fitting plane thickness. The WSA computer device 215 smooths the raw shape diameter scan profiles by the moving average with the defined window size. The WSA computer device 215 calculates the ideal shape diameter scan profiles by each raw shape diameter scan profile with one dimensional polynomial fitting. The WSA computer device 215 determines the delta of shape diameter scan profiles equals the raw shape diameter scan profiles minus the ideal shape diameter scan profiles.

The WSA computer device 215 calculates the weighting profiles by delta shape variation and slope changes within the defined moving windows along the diameter direction. The thresholds are also defined for catching high variation and slope changes. The delta shape variation could be standard variation, variance, or range. The slope change means, for example, when the left side slope times the right side slope is negative.

The WSA computer device 215 analyzes the measurement data of the wafer to determine the profile of the wafer after slicing. If the determined profile exceeds any quality thresholds, then the WSA computer device 215 may determine that the slicer 205 or other device needs to be adjusted.

The next device in system 200 is the grinder 220, which may be single-sided or double-sided. Simultaneous double side grinding operates on both sides of a wafer at the same time and produces wafers with highly planarized surfaces. These grinders 220 use a wafer-clamping device to hold the semiconductor wafer during grinding. The clamping device typically comprises a pair of hydrostatic pads and a pair of grinding wheels. The pads and wheels are oriented in opposed relation to hold the wafer therebetween in a vertical orientation. The hydrostatic pads beneficially produce a fluid barrier between the respective pad and wafer surface for holding the wafer without the rigid pads physically contacting the wafer during grinding. This reduces damage to the wafer that may be caused by physical clamping and allows the wafer to move (rotate) tangentially relative to the pad surfaces with less friction. While this grinding process can improve flatness and/or parallelism of the ground wafer surfaces, it can cause degradation of the topology of the wafer surfaces. Specifically, misalignment of the hydrostatic pad and grinding wheel clamping planes are known to cause such degradation. Post-grinding polishing produces a highly reflective, mirrored wafer surface on the ground wafer but does not address topology degradation.

After the grinder 220 grinds the wafer, the wafer is analyzed by a second measurement device 225 which measures data to generate a profile for the ground wafer. At this point, the wafer is unetched and unpolished. The second measurement device 225 provides the measurement data from the ground wafer to the WSA computer device 215 (which may include one or more computing devices). In some embodiments, the second measurement device 225 is a high accuracy, optical inspection tool (e.g., a WaferSight™ 2 or 2+ bare wafer geometry metrology system manufactured by KLA-Tencor Corporation) that uses light reflected from a surface of the wafer to detect very small surface variations. The second measurement device 225 (e.g., an optical inspection tool) is suitably capable of generating measurement data that is used by the WAS computing device 215 to analyze a nanotopography of the surface of the wafer.

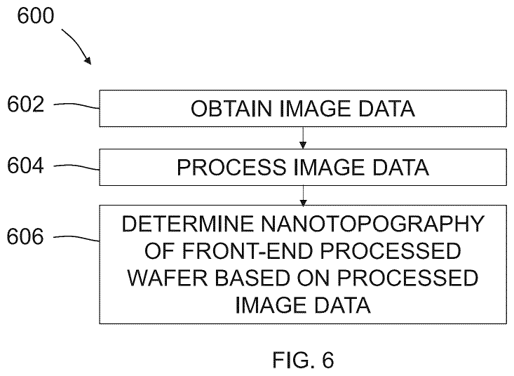

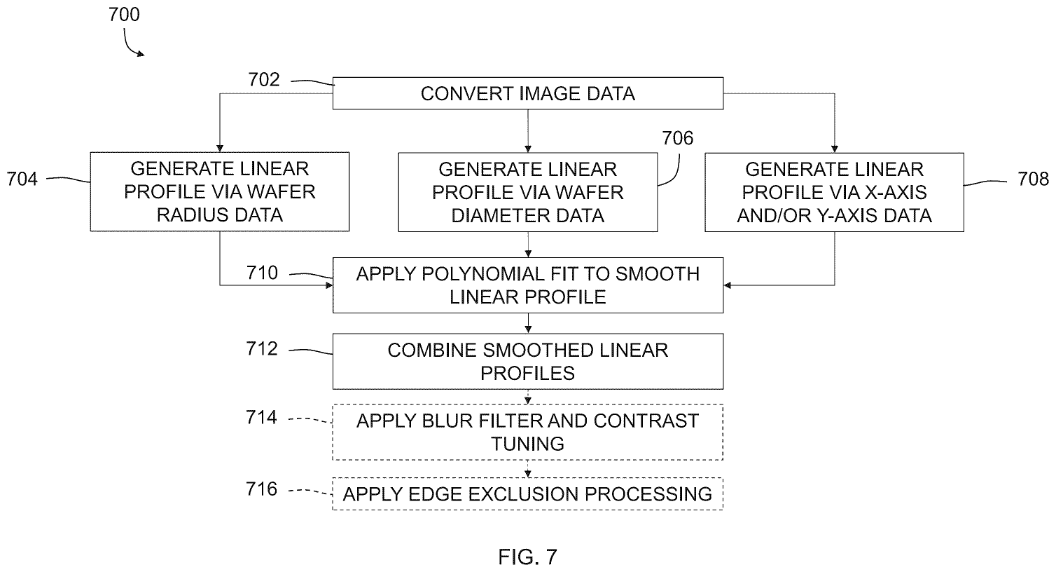

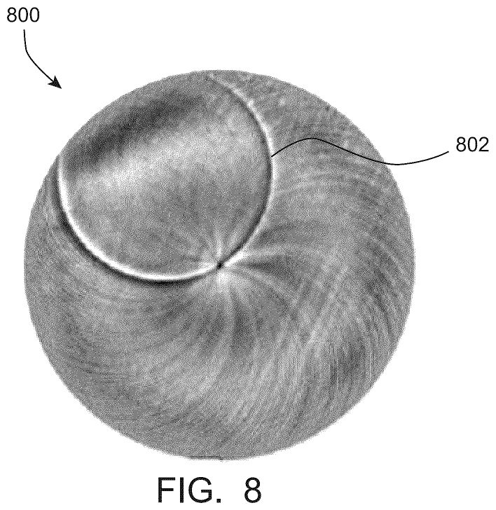

The measurement data generated by the second measurement device 225 may be distorted by noise resulting from surface defects on the ground wafer surface (e.g., grinding and wheel spark out marks). Such defects are shown in FIG. 8, which is a grayscale image of a surface of a wafer 800 generated by a WSA computing device 215 from data obtained via the second measurement device 225 (e.g., a WaferSight™ 2 or 2+). One such surface defects is indicated by 802 in FIG. 8. The WSA computing device 215 executes a wafer surface analysis model is executed that enables the computing device to filter out the noise in the measurement data resulting from the roughness defects and analyze the nanotopography of the surface of the ground wafer with greater accuracy. An example process flow of the model will be described with reference to FIGS. 6 and 7 below. Advantageously, analyzing the nanotopography of the wafer with relatively high accuracy at this stage can be used to determine if adjustments need to be made to the front-end process tool (e.g., grinder) based on the state of the front-end processed wafer surface and one or more predetermined thresholds. This reduces costs and manufacturing time spent on out of specification wafers, increases efficiency, and can improve yield. The analyzed nanotopography can be measured against one or more predetermined thresholds. In the example embodiment, some of the predetermined thresholds and/or requirements are based on one or more user preferences, from the manufacturer of the wafer and/or the customer purchasing the wafer.

In the example embodiment, the WSA computing device 215 can execute the wafer analysis model to determine that another grinding process with adjusted parameters should be performed on the wafer (e.g., to correct misalignment of the hydrostatic pad and grinding wheel clamping planes). For example, if the analyzed nanotopography exceeds any quality thresholds, then the WSA computer device 215 may determine that the grinder 220 or other device needs to be adjusted.

The system 200 may include a plurality of grinders 220, where each grinder 220 grinds a wafer, but each wafer may only be ground once. In these embodiments, the WSA computer device 215 tracks the grinding results of each of the plurality of grinders 220, and can pinpoint the source of topology degradation and facilitate efficient and accurate determination of the process adjustments that need to be made to correct any process errors.

The WSA computing device can also execute the wafer analysis model to determine that the wafer has suitable nanotopography for post-grinding processing. The surface condition of front-end processed (i.e., sawed and ground) wafers after the grinder(s) 220 is still relatively rough and generally not suitable for lithographic processing, which requires a particularly flat surface. The system 200 includes a plurality of post grinding devices, such as, but not limited to, an etching device (not shown) for etching the ground wafer and a polishing device 230 for polishing the etched wafer. In other embodiments, other devices, including other measurement devices for monitor the surface, flatness, and shape state of the wafer during the post-griding processes, may be included in the system 200. The polishing device 230 is used to polish one or both surfaces of the “front-end processed” wafer. The phrase “front-end processed” refers to a wafer before any polishing operation is performed thereon. This can include sawed and/or ground wafers. In the example embodiment, the front-end processed wafer has been ground but not etched or polished. As used herein, “in-process” is a wafer that has a front surface that has been intermediate and/or finish polished. In the example embodiment, the in-process wafer has been etched and polished.

The polishing device 230 can be used to perform an intermediate polishing operation and/or a finish polishing operation. The polishing device 230 can include one or more polishing devices for executing multiple different polishing operations. In an intermediate polishing operation, the front surface of the front-end processed wafer is polished to improve flatness and remove handling scratches. In a finish polishing operation, the front surface of the wafer is finish polished to remove fine or “micro” scratches from the front surface and to produce a highly-reflective, damage-free front surface of the wafer.

After the polishing device 230, and optionally after additional patterning processing steps, a high accuracy inspection tool (e.g., a WaferSight™ 2 or 2+ bare wafer geometry metrology system manufactured by KLA-Tencor Corporation) may be used to determine the shape and flatness of the in-process wafer, as well as other parameters such as nanotopography. From these measurements, known metrics may be used to predict overlay errors for at least a first lithographic patterning step.

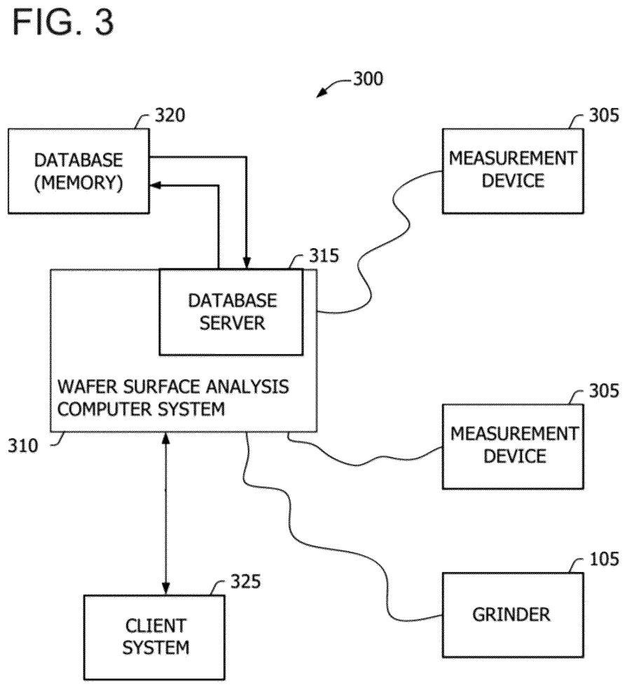

FIG. 3 is a simplified block diagram of an example system 300 for evaluating a wafer using a process 600 (shown in FIG. 6) in accordance with the system 200 (shown in FIG. 2). In the example embodiment, the system 300 is used for analyzing front-end processed wafers to determine whether they have suitable nanotopography such that they will be within tolerance post-polishing. In addition, the system 300 is a real-time data analyzing and classifying computer system that includes a wafer surface analysis (WSA) computer device 310 (also known as a WSA server) configured to analyze wafers and, in some embodiments, predict future states based on the analysis.

The system 300 includes one or more measurement devices 305 (e.g., a WaferSight™ 2 or 2+ bare wafer geometry metrology system manufactured by KLA-Tencor Corporation) configured to scan the surface of a wafer to generate a profile of that wafer. More specifically, the measurement device 305 scans the nanotopography of the wafer and is in communication with the WSA computer device 310. The measurement device 305 connects to the WSA computer device 310 through various wired or wireless interfaces including without limitation a network, such as a local area network (LAN) or a wide area network (WAN), dial-in-connections, cable modems, Internet connection, wireless, and special high-speed Integrated Services Digital Network (ISDN) lines. The measurement device 305 receives data about the surface of a wafer and reports that data to the WSA computer device 310. In other embodiments, the measurement device 305 is in communication with one or more client systems 325 and the client systems 325 route the measurement data to the WSA computer device 310 in real-time or near real-time. In some embodiments, a first measurement device 305 measures one side of the wafer and a second measurement device 305 measures the other side of the wafer. In the example embodiment, each one of the measurement devices 305 is similar to one of the first measurement device 210 and the second measurement device 225 (shown in FIG. 2).

The WSA computing device 310 is programmed to analyze the nanotopography of front-end processed wafers by filtering out surface roughness defects (e.g., grinding and wheel spark out marks) that typically create too much noise in the measurement data to accurately determine the nanotopography of the front-end processed wafer. Referring to FIG. 6, the WSA device 310 is programmed to perform the process 600 that includes 1) at step 602, obtaining image data of a surface of the front-end processed wafer from the measurement device 305; 2) at step 604, processing the image data to filter out surface roughness defects (or any noise in the measurement data resulting from the surface roughness defects); and 3), at step 604, determining nanotopography of the front-end processed wafer based on processed image data. Based on the determination at step 604, the WSA computing device 310 can predict a post-polishing state of the wafer based on the current nanotopography conditions and the model; and/or determine if adjustments need to be made to the wafer processing device based on the nanotopography state of the wafer and one or more predetermined thresholds. In the example embodiment, the WSA server 310 is similar to wafer surface analysis computer device 215 (shown in FIG. 2).

Client systems 325 are computers that include a web browser or a software application, which enables client systems 325 to communicate with the WSA server 310 using the Internet, a local area network (LAN), or a wide area network (WAN). In some embodiments, client systems 325 are communicatively coupled to the Internet through many interfaces including, but not limited to, at least one of a network, such as the Internet, a LAN, a WAN, or an integrated services digital network (ISDN), a dial-up-connection, a digital subscriber line (DSL), a cellular phone connection, a satellite connection, and a cable modem. Client systems 325 can be any device capable of accessing a network, such as the Internet, including, but not limited to, a desktop computer, a laptop computer, a personal digital assistant (PDA), a cellular phone, a smartphone, a tablet, a phablet, or other web-based connectable equipment.

A database server 315 is communicatively coupled to a database 320 that stores data. In one embodiment, database 320 is a database that includes historical data and the model. In some embodiments, database 320 is stored remotely from WSA server 310. In some embodiments, database 320 is decentralized. In the example embodiment, a person can access database 320 via client systems 325 by logging onto WSA server 310.

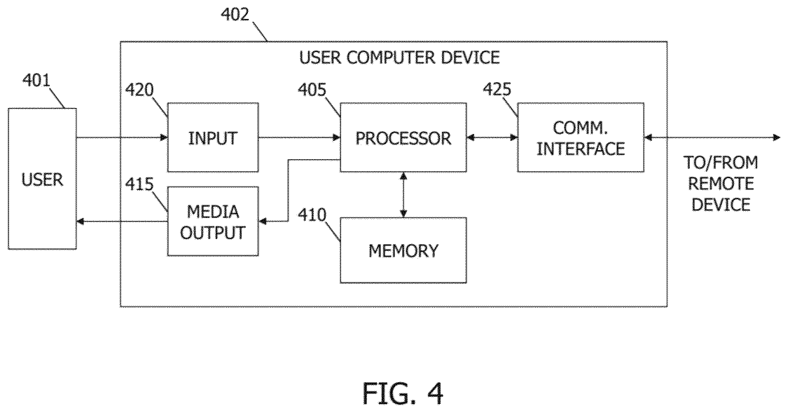

FIG. 4 illustrates an example configuration of client system 325 (shown in FIG. 3). User computer device 402 is operated by a user 401. User computer device 402 may include, but is not limited to, first measurement device 210, second measurement device 225, wafer surface analysis computer device 215, measurement device 305, WSA computer device 310, and client systems 325. User computer device 402 includes a processor 405 for executing instructions. In some embodiments, executable instructions are stored in a memory area 410. Processor 405 may include one or more processing units (e.g., in a multi-core configuration). Memory area 410 is any device allowing information such as executable instructions and/or transaction data to be stored and retrieved. Memory area 410 may include one or more computer-readable media.

User computer device 402 also includes at least one media output component 415 for presenting information to user 401. Media output component 415 is any component capable of conveying information to user 401. In some embodiments, media output component 415 includes an output adapter (not shown) such as a video adapter and/or an audio adapter. An output adapter is operatively coupled to processor 405 and operatively coupleable to an output device such as a display device (e.g., a cathode ray tube (CRT), liquid crystal display (LCD), light emitting diode (LED) display, or “electronic ink” display) or an audio output device (e.g., a speaker or headphones). In some embodiments, media output component 415 is configured to present a graphical user interface (e.g., a web browser and/or a client application) to user 401. A graphical user interface may include, for example, an interface for viewing the results of the analysis of one or more wafers. In some embodiments, user computer device 402 includes an input device 420 for receiving input from user 401. User 401 may use input device 420 to, without limitation, select a wafer to view the analysis of. Input device 420 may include, for example, a keyboard, a pointing device, a mouse, a stylus, a touch sensitive panel (e.g., a touch pad or a touch screen), a gyroscope, an accelerometer, a position detector, a biometric input device, and/or an audio input device. A single component such as a touch screen may function as both an output device of media output component 415 and input device 420.

User computer device 402 may also include a communication interface 425, communicatively coupled to a remote device such as WSA server 310 (shown in FIG. 3). Communication interface 425 may include, for example, a wired or wireless network adapter and/or a wireless data transceiver for use with a mobile telecommunications network.

Stored in memory area 410 are, for example, computer-readable instructions for providing a user interface to user 401 via media output component 415 and, optionally, receiving and processing input from input device 420. A user interface may include, among other possibilities, a web browser and/or a client application. Web browsers enable users, such as user 401, to display and interact with media and other information typically embedded on a web page or a website from WSA server 310. A client application allows user 401 to interact with, for example, WSA server 310. For example, instructions may be stored by a cloud service, and the output of the execution of the instructions sent to the media output component 415.

Processor 405 executes computer-executable instructions for implementing aspects of the disclosure. In some embodiments, the processor 405 is transformed into a special purpose microprocessor by executing computer-executable instructions or by otherwise being programmed.

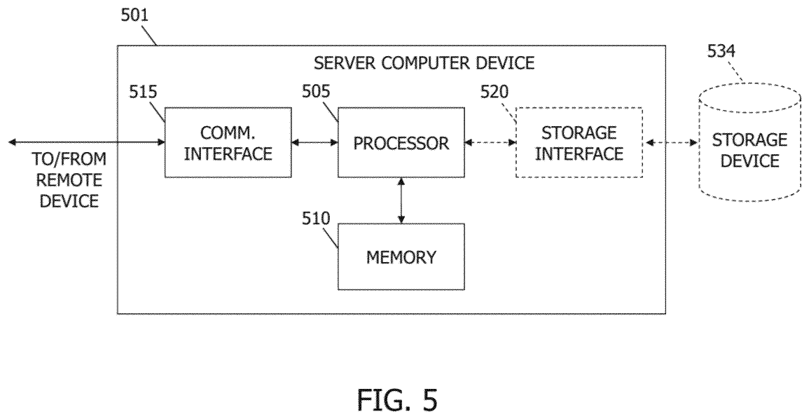

FIG. 5 illustrates an example configuration of the server system 310 shown in FIG. 3. Server computer device 501 may include, but is not limited to, WSA computer device 215, database server 315, and WSA server 310. Server computer device 501 also includes a processor 505 for executing instructions. Instructions may be stored in a memory area 510. Processor 505 may include one or more processing units (e.g., in a multi-core configuration).

Processor 505 is operatively coupled to a communication interface 515 such that server computer device 501 is capable of communicating with a remote device such as another server computer device 501, another WSA server 310, or client system 325 (shown in FIG. 3). For example, communication interface 515 may receive requests from client system 325 via the Internet, as illustrated in FIG. 3.

Processor 505 may also be operatively coupled to a storage device 534. Storage device 534 is any computer-operated hardware suitable for storing and/or retrieving data, such as, but not limited to, data associated with database 320 (shown in FIG. 3). In some embodiments, storage device 534 is integrated in server computer device 501. For example, server computer device 501 may include one or more hard disk drives as storage device 534. In other embodiments, storage device 534 is external to server computer device 501 and may be accessed by a plurality of server computer devices 501. For example, storage device 534 may include a storage area network (SAN), a network attached storage (NAS) system, and/or multiple storage units such as hard disks and/or solid state disks in a redundant array of inexpensive disks (RAID) configuration.

Processor 505 may be operatively coupled to storage device 534 via a storage interface 520. Storage interface 520 is any component capable of providing processor 505 with access to storage device 534. Storage interface 520 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 505 with access to storage device 534.

Processor 505 executes computer-executable instructions for implementing aspects of the disclosure. In some embodiments, the processor 505 is transformed into a special purpose microprocessor by executing computer-executable instructions or by otherwise being programmed. For example, the processor 505 is programmed with instructions such as illustrated in FIGS. 6 and 7.

FIG. 6 is a flowchart illustrating an example process 600 of evaluating a wafer (e.g., the substrate 100 in FIG. 1) using the system 200 (shown in FIG. 2). In the example embodiment, steps of process 600 are performed by the WSA computer device 215 (shown in FIG. 2).

At step 602, image data of the wafer is obtained from a flatness inspection tool capable of detecting very small surface variations for nanotopography analysis of the surface of the wafer. The wafer is a front-end processed wafer at this stage, meaning it has been sawed and/or ground and not yet polished. As a result, the surface of the wafer can have surface roughness defects that can distort the image data obtained from the flatness inspect tool. In the example embodiment, the image data is obtained from the second measurement device 225 (FIG. 2) following the grinder 220. For example, the image data is obtained using a high accuracy, optical inspection tool suitably for nanotopography analysis (e.g., a WaferSight™ 2 or 2+ bare wafer geometry metrology system manufactured by KLA-Tencor Corporation). The input from the nanotopography tool can be front side shape or nanotopography of the wafer, and can be grid data or an image.

At step 604, the WSA computer device 215 executes a wafer analysis model or algorithm that filters out any surface roughness defects that can distort or create noise in the image data obtained at 602. Filtering out the surface roughness defects (e.g., grinding or wheel spark out marks) from the image data can then be used to calculate more accurate nanotopography. In the example embodiment, the surface roughness defects are filtered out of the image data by processing the image data according to the process flow 700 shown in FIG. 7. In some embodiments, processing the image data at step 604 is performed using a Python script (numpy, opencv, matplotlib, etc.) to process a nanotopography map or grid data obtained as the image data at 602 via the nanotopography tool and remove any surface roughness defects.

Referring to FIG. 7, the image data obtained at 602 from the nanotopography tool is converted at step 702 to gray scale. For example, the grid data (using fixed scale range, for example −125˜125 nm, is mapped to gray scale 0˜255) or image obtained in the image data can be converted to an 8 bit grayscale image array. A converted image of a surface of a wafer 800 is shown in FIG. 8.

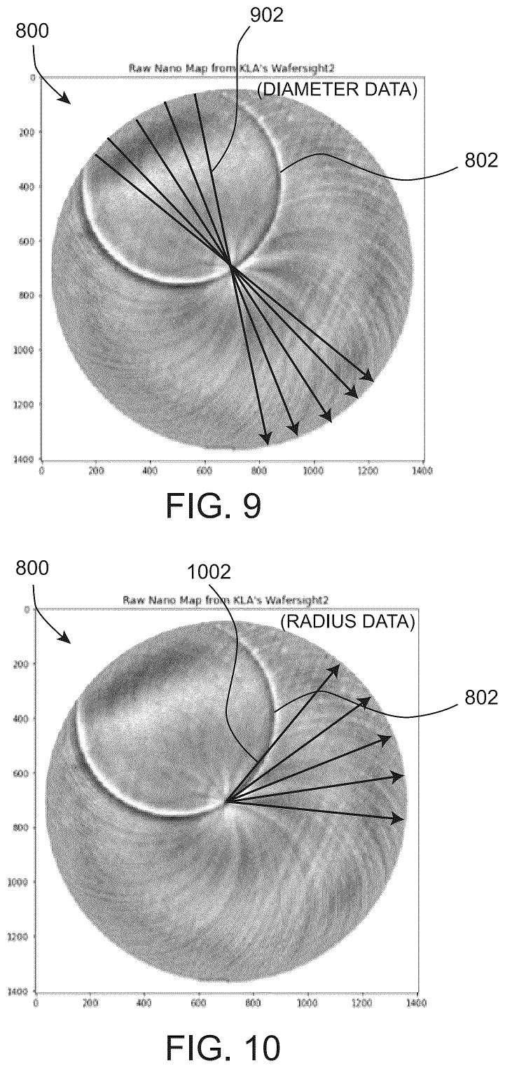

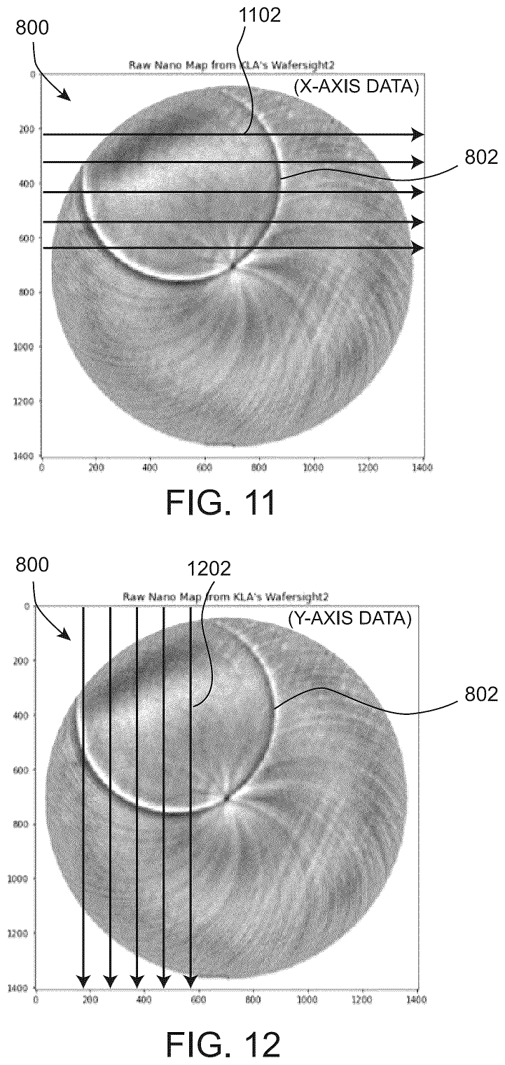

As shown in FIG. 8, the nanomap of the converted image data includes a surface roughness defect or feature 802 of the front-end process (as-ground) wafer (e.g., grinding or wheel spark out marks). The surface roughness feature 802 impedes the ability to accurately determine nanotopography of the wafer. Accordingly, the process flow includes further processing of the converted image to smooth the converted image data. In particular, the example process includes generating linear profiles that are subsequently smoothed to remove the roughness feature 802 from the image (i.e., mitigate or eliminate its impact on the ability to determine nanotopography from the image). This includes generating linear profiles of the grayscale image, which are depicted in FIGS. 9-12 respectively at 902 (linear profiles taken along diameters of the wafer), 1002 (linear profiles taken along a radius of the wafer), 1102 (linear profiles taken along an X-axis direction), or 1202 (linear profiles taken along a Y-axis direction). The linear profiles can be generated from the two dimensional rows and/or columns of the converted image data. With additional reference to FIGS. 9-12, the linear profiles can be generated via 2D data as radial profiles 1002 (step 704, FIG. 10), as diameter profiles 902 (step 706, FIG. 9), as x-axis profiles or rows 1102 from the 2D data (step 708, FIG. 11), and/or as y-axis profiles or columns 1202 from the 2D data (step 708, FIG. 12).

To further illustrate, the converted image data is in 2D forms with rows and columns. In the example embodiment, the x-axis linear profiles 1102 (FIG. 11) are used. In this embodiment, the grayscale of each pixel is taken row by row (x=column 0 to image width, y=pixel grayscale 0-255). In embodiments where the y-axis profiles 1202 are used, the grayscale of each pixel is taken column-by-column (x=pixel grayscale 0-255, y=row 0 to column height). In examples where radial profiles 1002 or diameter profiles 902 are used, then polar coordiantes of the grayscale of each pixel is taken (e.g., by each 1 degree). The number of linear profiles will be based on incoming image, for example by Wafersight, which has 660 rows.

Once the linear profiles are generated, at step 710, the process 700 includes applying a regression analysis, such as high-order (e.g., 9, 11, 15, or 17) polynomial fit, to smooth each linear profile. Then at step 712, the smoothed linear profiles are recombined to produce smoothed (polynomial filtered) grayscale data. For example, a Python script configured to execute the process 700 can generate a new image according to the high order polynomial filtered grayscale values.

Following the recombining of the smoothed linear profiles at step 712, the image data can be used to analyze nanotopography of the wafer surface (at step 606 of process 600) with relatively high accuracy. The analyzed nanotopography can be measured against one or more predetermined thresholds. In the example embodiment, some of the predetermined thresholds and/or requirements are based on one or more user preferences, from the manufacturer of the wafer and/or the customer purchasing the wafer. Following step 606 of the process 600, the wafer can either be sorted for post-grinding processing (e.g., polishing) or a determination may be made that the wafer needs additional front-end processing (e.g., grinding) and the front end process tool (e.g., the grinder 220) can be adjusted accordingly to compensate for any topology degradation.

Referring again to FIG. 7, in some embodiments, the process 700 can also include applying a blur filter on the smoothed, recombined image data at step 714. Example blur filters include a 2D average blur filter with a defined moving window size, a median blur filter, or a Gaussian blur filter. Additionally or alternatively, contrast tuning may be applied to the recombined image data at step 714 (e.g., using the addWeighted function of Python OpenCV).

In some embodiments, edge exclusion processing at step 716 may be applied to eliminate peripheral edge portions of the wafer from the nanotopography analysis. This may be dictated by manufacturer or customer preferences. For example, the edge exclusion process may be applied in a range of 10 mm to 20 mm from the peripheral edge. The effective area for the nanotopography analysis will be a circle or radius 130 mm-140 mm in diameter. The WSA computing device 215 can generate a mask image with white filled circle with the appropriate radial size (proportional by original NT image or grid data), and apply the mask on the smoothed nanotopography image.

At step 606 of the process 600, following the recombining of the smoothed profiles at 712 and, optionally, applying blur filtering and/or contrast tuning at 714 and/or applying edge exclusion processing at 716, the WSA computer device 215 calculates nanotopography of the wafer. Nanotopography can be calculated as Nanotopography parameters such as THA1010 or THA2525. THA1010 and THA2525 are Nanotopography Parameters calculated based on Nanotopography Maps. THA1010 is calculated by recording peak to valley difference value in a moving window of 10 mm by 10 mm size, that is moved over the entire wafer and then a certain percentile of this recorded values set is deemed as the THA1010 value. The percentile value can vary and is usually specified by the end consumer. THA2525 is similar to THA1010, except that the window can be a 25 mm by 25 mm square or a circle with a diameter of 25 mm.

The WSA computer device 215 can then compares the calculated wafer nanotopography to one or more predetermined thresholds. In the example embodiment, the predetermined thresholds are requirements for the proper surface of the wafer post polishing. In the example embodiment, some of the predetermined thresholds and/or requirements are based on one or more user preferences, from the manufacturer of the wafer and/or the customer purchasing the wafer.

If the wafer attributes (nanotopography) are within tolerances the WSA computer device 215 may indicate that the wafer is suitable for polishing, and the wafer can then be sorted as appropriate. If the wafer attributes are not within tolerances, then the WSA computer device 215 triggers an alert and potentially adjusts one or more front end process devices, such as, but not limited to, the slicer 205, the grinder 220, the polishing device 230, or another device. In some embodiments, the WSA computer device 215 directly adjusts the device(s). In other embodiments, the WSA computer device 215 instructs another device to adjust the device(s). In still further embodiments, the WSA computer device 215 instructs a user to adjust the device(s).

### Examples

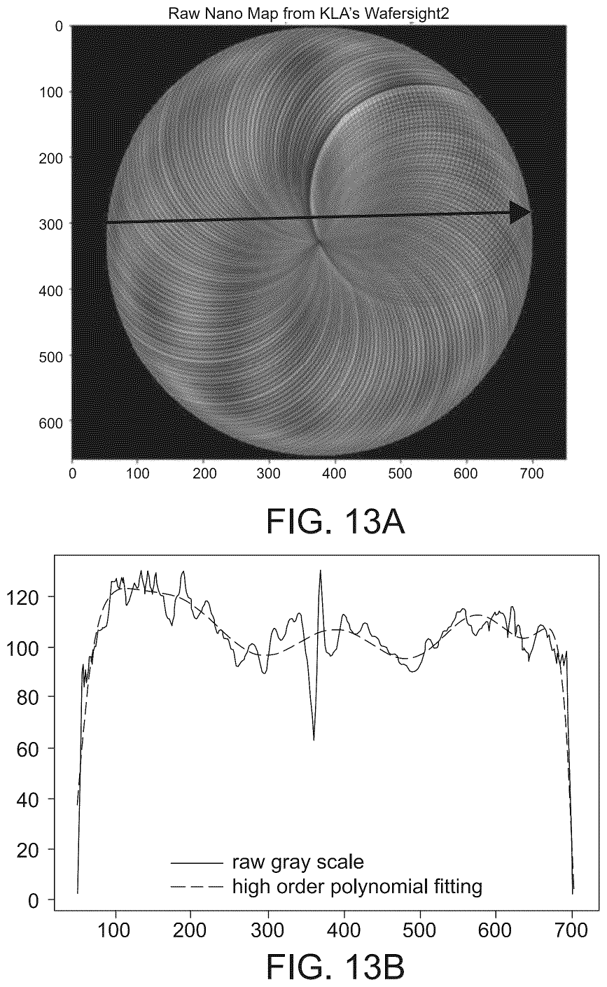

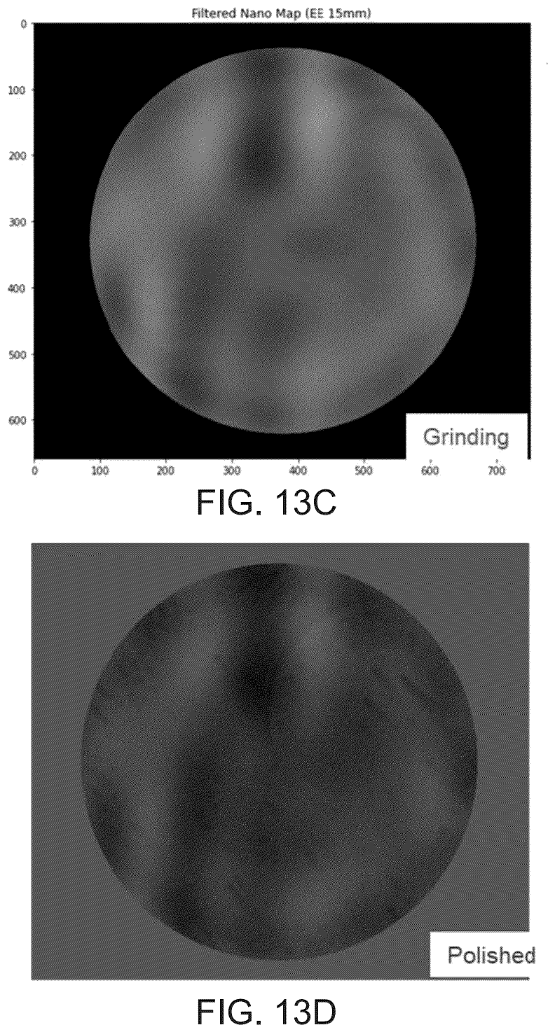

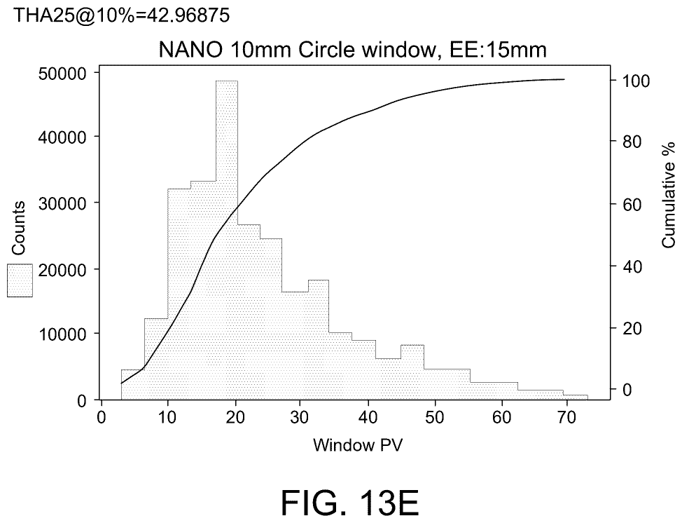

Example 1: FIGS. 13A-13E show that grinding mark and wheel spark out marks on a surface of a wafer (shown in FIG. 13A in the grayscale converted image) are removed in the smoothed image data (FIG. 13C) generated by applying high-order (e.g., 9, 11, 15, or 17) polynomial fit to X-axis linear profiles (FIG. 13B). The smoothed image data (FIG. 13C) correlates well to data from the polished wafer (FIG. 13D). THA25 has been recalculated (FIG. 13E).

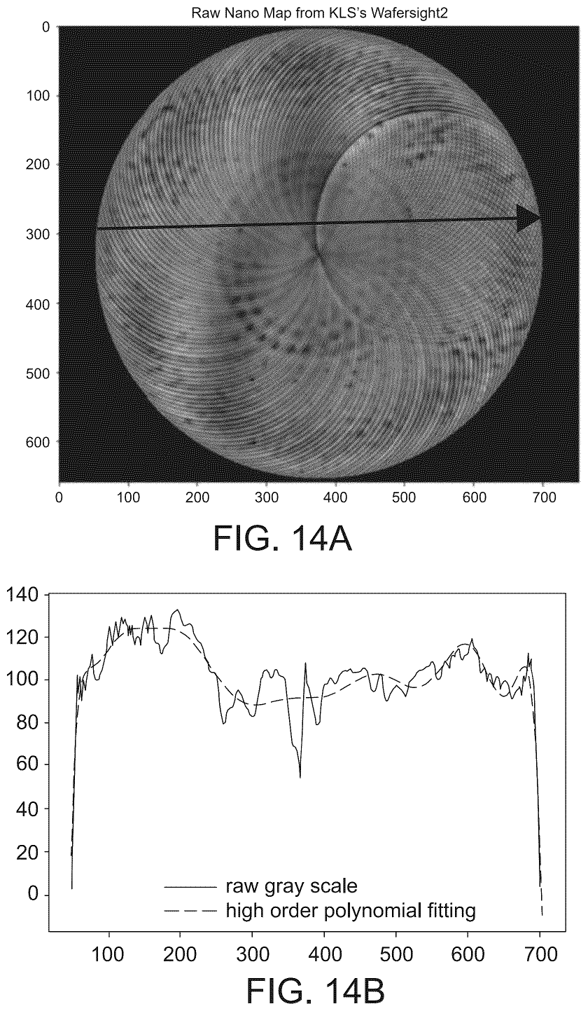

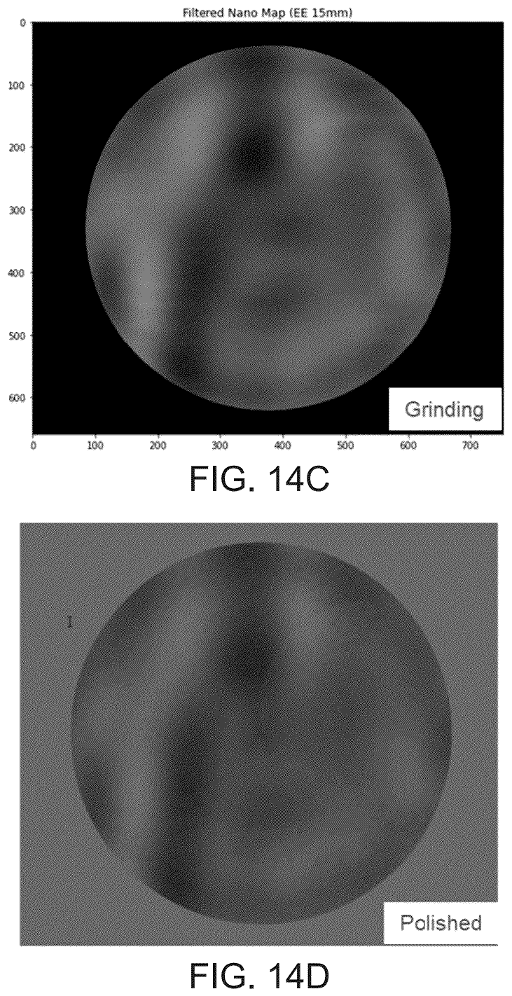

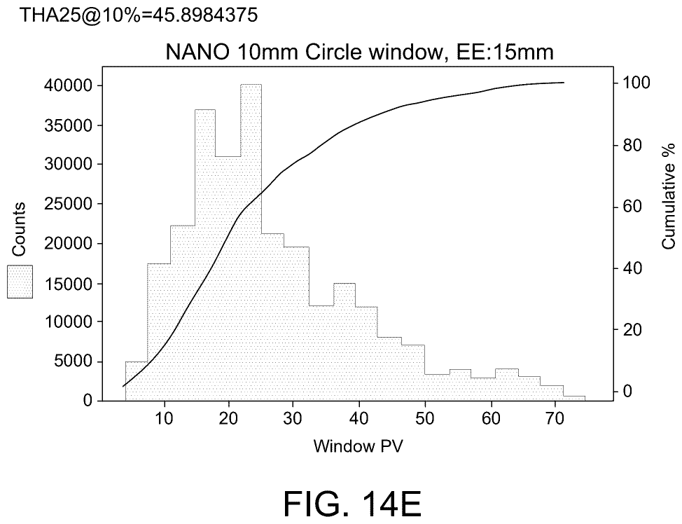

Example 2: FIGS. 14A-14E show that chuck marks, contaminations, and wheel spark out marks on a surface of a wafer (shown in FIG. 14A in the grayscale converted image) are removed in the smoothed image data (FIG. 14C) generated by applying high-order (e.g., 9, 11, 15, or 17) polynomial fit to X-axis linear profiles (FIG. 14B). The smoothed image data (FIG. 14C) correlates well to data from the polished wafer (FIG. 14D). THA25 has been recalculated (FIG. 14E).

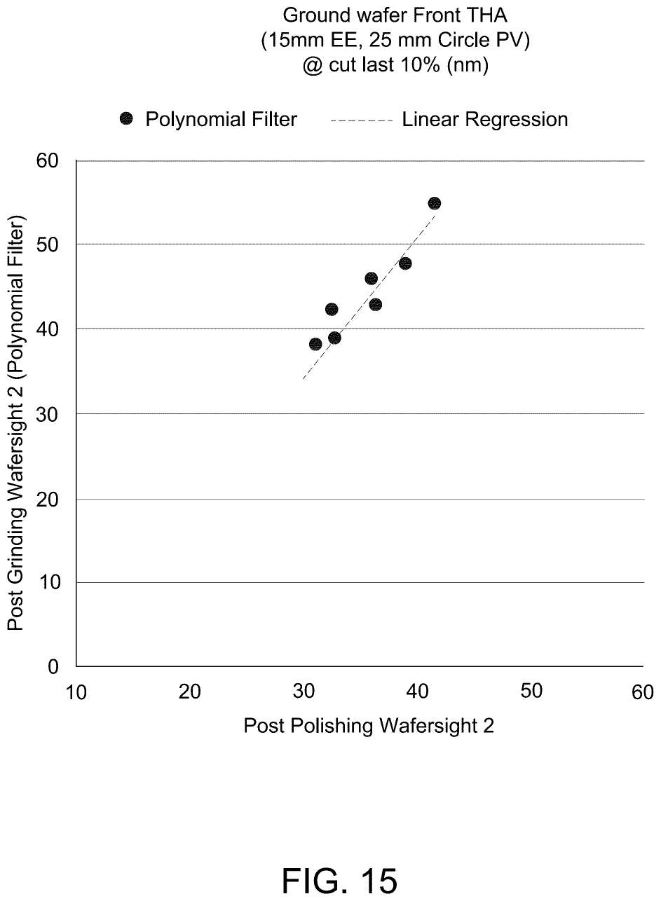

FIG. 15 shows comparison data between polynomial filter processing on ground wafer surfaces and Wafersight OA reprocessing data on post-polished wafers. As illustrated in FIG. 15, there is a good correlation (R²=0.81) between the polynomial filter processing and the post-polished wafers.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A method of processing semiconductor wafers, the method comprising:
obtaining, with an inspection tool, image data of a surface of a pre-polished wafer;
processing, with a computing device in communication with the inspection tool, the image data by:
generating linear profiles of the surface,
applying a regression analysis to smooth each linear profile, and
recombining the smoothed linear profiles to obtain processed image data;
determining, with the computing device, a nanotopography of the surface of the pre-polished wafer from the processed image data; and
based on the determined nanotopography of the surface, either:
sorting the pre-polished wafer for polishing; or
adjusting a front end process performed on the pre-polished wafer.

2. The method of claim 1, wherein applying the regression analysis includes applying a polynomial fit to smooth each linear profile.

3. The method of claim 2, wherein the polynomial fit is an order of nine (9) or more.

4. The method of claim 1, wherein each linear profile is generated between a center of the surface and a peripheral edge of the wafer.

5. The method of claim 1, wherein each linear profile is generated along a diameter of the wafer.

6. The method of claim 1, wherein the wafer defines a central axis extending through a center of the surface of the wafer in a first direction, wherein each linear profile is generated along the surface of the wafer in a second direction that is perpendicular to the first direction.

7. The method of claim 1, further comprising applying, with the computing device, a blur filter to the processed image data prior to determining the nanotopography of the surface of the pre-polished wafer.

8. The method of claim 1, further comprising tuning, with the computing device, a contrast of the processed image data prior to determining the nanotopography of the surface of the pre-polished wafer.

9. The method of claim 1, wherein the image of the surface of the pre-polished wafer is obtained using an optical wafer inspection tool.

10. The method of claim 1, wherein the pre-polished wafer includes a roughness feature on the surface that increases a roughness of the surface.

11. The method of claim 10, wherein the roughness feature includes one or more marks on the surface from a grinding operation.

12. The method of claim 1, wherein the wafer is a single crystal silicon wafer.

13. A system for processing semiconductor wafers, the system comprising:
one or more front end process devices;
an inspection tool configured to obtain image data of a surface of a pre-polished wafer; and
a computer device in communication with the one or more front end process devices and the inspection tool, the computer device comprising at least one processor in communication with at least one memory device, wherein the at least one processor is programmed to:
generate linear profiles of the surface;
apply a regression analysis to smooth each linear profile;
recombine the smoothed linear profiles to obtain processed image data;
determine a nanotopography of the surface of the pre-polished wafer from the processed image data; and
based on the determined nanotopography of the surface, adjust a front end process performed by the one or more front end process devices on the pre-polished wafer.

14. The system of claim 13, wherein the at least one processor is further programmed to apply the regression analysis by applying a polynomial fit to smooth each linear profile.

15. The system of claim 14, wherein the at least one processor is further programmed to apply the polynomial fit by applying a polynomial fit having an order of nine (9) or more.

16. The system of claim 13, wherein the at least one processor is further programmed to generate the linear profiles of the surface by generating each linear profile between a center of the surface and a peripheral edge of the wafer.

17. The system of claim 13, wherein the at least one processor is further programmed to generate the linear profiles of the surface by generating each linear profile along a diameter of the wafer.

18. The system of claim 13, wherein the wafer defines a central axis extending through a center of the surface of the wafer in a first direction, wherein the at least one processor is further programmed to generate the linear profiles of the surface by generating each linear profile along the surface of the wafer in a second direction that is perpendicular to the first direction.

19. The system of claim 13, wherein the at least one processor is further programmed to apply a blur filter to the processed image data prior to determining the nanotopography of the surface of the pre-polished wafer.

20. The system of claim 13, wherein the at least one processor is further programmed to tune a contrast of the processed image data prior to determining the nanotopography of the surface of the pre-polished wafer.

21. The system of claim 13, wherein the inspection tool comprises an optical wafer inspection tool.

22. The system of claim 13, wherein the one or more front end process devices comprises a slicer, a grinder, or a polishing device.
